(19) United States
(12) Patent Application Publication
(10) Pub. No.: US 2010/0243030 A1
(43) Pub. Date: Sep. 30, 2010

(54) SUBSTRATE AND POSITIONING METHOD THEREOF, PHOTOELECTRIC CONVERSION DEVICE AND MANUFACTURING METHOD AND APPARATUS THEREFOR, AND SOLAR CELL

(75) Inventor: Haruo YAGO, Ashigarakami-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/749,332

(22) Filed: Mar. 29, 2010

(30) Foreign Application Priority Data
Mar. 27, 2009 (JP) 2009-078913

(51) Int. Cl. H01L 27/142; H01L 31/0216; H01L 31/18; G01B 11/14

(52) U.S. Cl. 136/244; 136/256; 438/80; 356/620; 257/E31.119; 257/E27.126

(57) ABSTRACT

A substrate of the invention has a positioning marker formed with a light absorbing agent that selectively absorbs light of a specific wavelength region or with a light reflecting agent that selectively reflects light of a specific wavelength region. Preferably, the light of a specific wavelength range is near infrared light, infrared light, near ultraviolet light, or ultraviolet light. Preferably, the positioning marker is formed on a rear surface of the substrate.

### BACKGROUND OF THE INVENTION

1. Field of the Invention

The present invention relates to a substrate suitable for use with a photoelectric conversion device and a positioning method thereof, a photoelectric conversion device and a manufacturing method and apparatus therefor, and a solar cell that uses the photoelectric conversion device.

2. Description of the Related Art

Photoelectric conversion devices having a laminated structure of a lower electrode (rear electrode), a photoelectric conversion semiconductor layer that generates a current by absorbing light, and an upper electrode are used in various applications, such as solar cells and the like. Most of the conventional solar cells are Si-based cells that use bulk monocrystalline Si, polycrystalline Si, or thin film amorphous Si. Recently, however, research and development of compound semiconductor-based solar cells that do not depend on Si has been carried out. Two types of compound semiconductor-based solar cells are known, one of which is a bulk system, such as GaAs system and the like, and the other of which is a thin film system, such as CIS (Cu—In—Se) system formed of a group Ib element, a group IIIb element, and a group VIb element, CIGS (Cu—In—Ga—Se) , or the like. The CIS system or CIGS system has a high light absorption rate, and high energy conversion efficiency is reported.

In various fields of electronic devices, including thin film photoelectric conversion devices, technical development for forming and processing various functions of a device on a flexible substrate, thereby fabricating the entire device in a thin plate-like shape, has been underway. Such technology may reduce the amount of raw materials used and allows a continuous production (roll-to-roll process) , resulting in a reduced manufacturing cost. Flexible substrates for photoelectric conversion devices include a substrate of metal base with an insulation film formed on the surface thereof.

Heretofore, integrated devices are monolithically fabricated for high efficiency and low cost. One of the key technologies for that purpose is to divide a film into many cells by providing grooves in the film. When forming the grooves that divide a film into many cells, it is necessary to detect the position of the substrate with a high degree of accuracy.

Japanese Unexamined Patent Publication Nos. 2003-110224 and 2000-183387 describe a method of detecting a position of a substrate by providing a positioning marker on the substrate. Claim 3 of Japanese Unexamined Patent Publication No. 2003-110224 discloses that the positioning for patterning of a substrate is performed with reference to a marker formed on the substrate, and a 1.5 mm hole provided in the substrate is cited as the marker in paragraph 0028. Claim 10 of Japanese Unexamined Patent Publication No. 2000-183387 discloses that, when an edge of a substrate which is not used for a photoelectric conversion device is eventually cut away, a cutting position signal is obtained by detecting a marker formed in the substrate, and a hole is illustrated in FIG. 2A as the marker. As disclosed in these documents, holes have conventionally been used commonly as the marker of substrates.

The markers of holes disclosed in Japanese Unexamined Patent Publication Nos. 2003-110224 and 2000-183387 require a cutting process for the markers and an essential cleaning process for cleaning the shavings generated by the cutting process. It is also necessary to form a marker by providing an edge which is not actually used for a photoelectric conversion device so that it is not possible to effectively use the entire substrate.

In the case of a semiconductor device, a Si wafer inherently has an unusable edge, so that the effective area of the substrate is not influenced by the provision of the marker in the edge. But, in the case of a photoelectric conversion device, elimination of the edge is desirable because it increases the effective area of the substrate and eliminates the cutting process for the edge.

The present invention has been developed in view of the circumstances described above and it is an object of the present invention to provide a substrate that allows a positioning marker to be formed easily and positioning of the substrate with a high degree of accuracy, and a positioning method thereof. It is a further object of the present invention to provide a substrate that allows a positioning marker to be formed without providing an edge which is not actually used in the substrate and a positioning method thereof. It is a still further object of the present invention to provide a photoelectric conversion device using the substrate described above and a method and apparatus for manufacturing the device.

### SUMMARY OF THE INVENTION

A substrate of the present invention is a substrate having a positioning marker formed with a light absorbing agent that selectively absorbs light of a specific wavelength region or with a light reflecting agent that selectively reflects light of a specific wavelength region.

A photoelectric conversion device of the present invention is a device, including a substrate on which a laminated structure is formed, the laminated structure including a lower electrode, a photoelectric conversion layer that generates a current by absorbing light, and an upper electrode, and being divided into a plurality of cells by a plurality of grooves,

wherein the substrate has a positioning marker formed with a light absorbing agent that selectively absorbs light of a specific wavelength region or with a light reflecting agent that selectively reflects light of a specific wavelength region.

A solar cell of the present invention is a solar cell, including the photoelectric conversion device described above.

A substrate positioning method of the present invention is a method in which a substrate having a positioning marker formed with a light absorbing agent that selectively absorbs light of a specific wavelength region or with a light reflecting agent that selectively reflects light of a specific wavelength region is used and positioning of the substrate is performed by irradiating the positioning marker with detection light of the specific wavelength region and detecting reflection light from the positioning marker.

A photoelectric conversion device manufacturing method of the present invention is a method of manufacturing a photoelectric conversion device having a substrate on which a laminated structure is formed, the laminated structure including a lower electrode, a photoelectric conversion layer that generates a current by absorbing light, and an upper electrode, and being divided into a plurality of cells by a plurality of groove,

wherein, the method uses, as the substrate, a substrate having a positioning marker formed with a light absorbing agent that selectively absorbs light of a specific wavelength region or with a light reflecting agent that selectively reflects light of a specific wavelength region and has a process of performing positioning of the substrate by irradiating the marker with detection light of the specific wavelength region and detecting reflection light from the positioning marker.

In the photoelectric conversion device manufacturing method of the present invention, it is preferable that the method further includes, after the process of performing positioning of the substrate, a process of forming the plurality of grooves based on obtained position data of the substrate.

A photoelectric conversion device manufacturing apparatus of the present invention is an apparatus for manufacturing the photoelectric conversion device of the present invention described above, including: a light irradiation unit for irradiating the positioning marker with detection light of the specific wavelength range; and a detection unit for detecting reflection light from the positioning marker. Preferably, the photoelectric conversion device manufacturing apparatus of the present invention further includes a scriber for forming the plurality of grooves.

According to the present invention, a positioning marker can be formed easily on a substrate, and a substrate that enables the positioning thereof with a high degree of accuracy and a positioning method thereof can be provided. According to the present invention, a substrate that allows a positioning marker to be formed thereon without requiring an edge, which is not eventually used, in the substrate and a positioning method thereof can be provided. According to the present invention, a photoelectric conversion device using the substrate described above and a manufacturing method and apparatus therefor can be provided.

### BRIEF DESCRIPTION OF THE DRAWINGS

FIG. 1A is a schematic sectional view of a photoelectric conversion device according to an embodiment of the present invention taken along a lateral direction.

FIG. 1B is a schematic sectional view of a photoelectric conversion device according to an embodiment of the present invention taken along a longitudinal direction.

FIG. 2 illustrates sectional views of anodized substrates, illustrating the constructions thereof.

FIG. 3 is a perspective view of an anodized substrate, illustrating a manufacturing method thereof.

FIG. 4 is a plan view of an anodized substrate, illustrating the rear surface thereof.

FIG. 5 illustrates the relationship between the lattice constant and band gap of I-III-VI compound semiconductors.

FIG. 6 is a schematic perspective view of a manufacturing apparatus (scribing apparatus) according to an embodiment of the present invention.

### DESCRIPTION OF THE PREFERRED EMBODIMENTS

### [Substrate]

A substrate of the present invention is a substrate having a positioning marker formed with a light absorbing agent that selectively absorbs light of a specific wavelength or with a light reflecting agent that selectively reflects a light of a specific wavelength. There is not any specific restriction on the light absorption rate of the light absorbing agent or the light reflection rate of the light reflecting agent and they may be in a level that allows position detection.

There is not any specific restriction on the light of a specific wavelength and near infrared, infrared, near ultraviolet, or ultraviolet light is preferable.

The terms “near infrared light”, “infrared light”, “near ultraviolet light” and “ultraviolet light” as used herein refer to light with a wavelength in the range from 700 to 2500 nm, light with a wavelength in the range from 700 to 1000 nm, light with a wavelength in the range from 290 to 380 nm, and light with a wavelength in the range from 100 to 380 nm respectively.

There is not any specific restriction on the form of the light absorbing agent or the light reflecting agent, and a dye, a pigment, or an ink containing the dye or pigment, which is applicable to a substrate, is preferably used. Such a form allows the light absorbing agent or the light reflecting agent to be coat printed on a substrate in a desired pattern by an inkjet method or the like and thereafter to be heat dried, as required, whereby a positioning marker may be formed easily.

There is not any specific restriction on the light source of detection light. In the case of a marker that absorbs or reflects near infrared light or infrared light, a near infrared LED that emits near infrared light of 750 to 850 nm or the like may be used. In the case of a marker that absorbs or reflects near ultraviolet light or ultraviolet light, black light or the like may be used.

As for the light absorbing agent that absorbs near infrared light or infrared light, a dye or a pigment having the absorption maximum at a wavelength of 760 to 1200 nm disclosed in Japanese Unexamined Patent Publication No. 2008-284817, paragraph [0029] to paragraph [0041] may be cited. As for the dye that absorbs near infrared light or infrared light, any known dyes such commercially available dyes and those described, for example, in “Dye Handbook” (The Society of Synthetic Organic Chemistry, Japan, 1970) may be used. More specifically, such dyes include azo dyes, azo metal complex salt dyes, pyrazolone azo dyes, naphthoquinone dyes, anthraquinone dyes, phthalocyanine dyes, carbonium dyes, quinonimine dyes, methine dyes, cyanine dyes, squarylium dyes, pyrylium salt, metal thiolate complexes, and the like.

Preferable dyes include, for example, the cyanine dyes disclosed in Japanese Unexamined Patent Publication Nos. 58(1983)-125246, 59(1984)-084356, 60(1985)-078787, and the like, the methine dyes disclosed in Japanese Unexamined Patent Publication Nos. 58(1983)-173696, 58(1983)-181690, 58(1983)-194595, and the like, the naphthoquinone dyes disclosed in Japanese Unexamined Patent Publication Nos. 58(1983)-112793, 58(1983)-224793, 59(1984)-048187, 59(1984)-073996, 60(1985)-052940, 60(1985)-063744, and the like, the squarylium dye disclosed in Japanese Unexamined Patent Publication No. 58(1983)-112792, and the like, the cyanine dye disclosed in U.K. Patent No. 434,875, and the like.

The near infrared absorbing sensitizer disclosed in U.S. Pat. No. 5,156,938 is also preferably used. In addition, the following are also preferably used, the substituted arylbenzo (thio) pyrylium salt disclosed in U.S. Pat. No. 3,881,924, trimethine thia-pyrylium salt disclosed U.S. Pat. No. 4,327,169, pyrylium compounds disclosed in Japanese Unexamined Patent Publication Nos. 58(1983)-220143, 59(1984)-041363, 59 (1984) -084248, 59 (1984) -084249, 59 (1984) -146063, and 59(1984)-146061, cyanine pigment disclosed in U.S. Pat. No. 4,617,247, pentamethine thiopyrylium salt and the like disclosed in U.S. Pat. No. 4,283,475, and pyrylium compounds disclosed in Japanese Patent Publication Nos. 5(1993)-013514, 5(1993)-019702. Other preferable dye examples include the dyes that absorb near infrared light disclosed in U.S. Pat. No. 4,756,993 as Formulae (I) and (II).

Other preferable dye examples that absorb infrared light include certain indolenine cyanine dyes disclose in U.S. Pat. No. 6,797,449. Among the dyes, the cyanine dye, squarylium dyespyrylium salt, nickel thiolate complex, and indolenine cyanine dye are particularly preferable.

As for the pigment that absorbs near infrared light or infrared light, commercially available pigments and those described in “Color Index Handbook”, “Latest Pigment Handbook” (Nihon Pigment Technique Society, 1977), “Latest Pigment Application Technique” (CMC, 1986), and “Printing Ink Technique” (CMC, 1984) may be used.

Pigment types include, black pigments, yellow pigments, orange pigments, brown pigments, red pigments, purple pigments, blue pigments, green pigments, fluorescent pigments, metal powder pigments, and polymer binding pigments. More specifically, insoluble azo pigments, azo lake pigments, condensed azo pigments, chelate azo pigments, phthalocyanine pigments, anthraquinone pigments, perylene and perynone pigments, thioindigo pigments, quinacridone pigments, dioxazine pigments, isoindolinone pigments, quinophthalone pigments, in-mold decorating lake pigments, azine pigments, nitroso pigments, nitro pigments, natural pigments, fluorescent pigments, inorganic pigments, carbon blacks, and the like may be used.

As for the ink that absorbs near infrared light or infrared light, “Infrared Absorbing Ink Pro-JET” manufactured by FUJIFILM Corporation, and the like can be cited.

As for the light absorbing agent that absorbs near ultraviolet light or ultraviolet light, the agent described in Japanese Unexamined Patent Publication No. 2008-195830, paragraph [0028] to paragraph [0034] may be cited.

As for the light absorbing agent that absorbs near ultraviolet light or ultraviolet light, benzotriazoles, benzophenones, salicylic acids, cyanoacrylates, cyclic imino esters, and the like can be cited.

Examples of benzotriazole series ultraviolet absorbing agents include 2-(2′-hydroxyl-5′-methylphenyl)-2H -benzotriazole, 2-(2′-hydroxyl-5′-t-butylphenyl)-2H- benzotriazole, 2-(2′-hydroxyl-3′, 5′-di-t-butylphenyl)-2H-benzotriazole, 2-(2′-hydroxyl-3′-t-butyl-5′-methylphenyl)-2H-benzotriazole, 2-(2′-hydroxyl-5′-methylphenyl)-5-chloro-2H-benzotriazole, 2-(2′-hydroxyl-3′, 5′-di-t-amylphenyl)-2H-benzotriazole, 2-(2′-hydroxyl-5′-(methacryloyl oxymethyl) phenyl)-2H - benzotriazole, 2-(2′- hydroxyl-5′-(methacryloyl oxypropyl) phenyl)-2H - benzotriazole, 2-(2′-hydroxyl-3′-t-butyl-5′-(methacryloyl oxyethyl) phenyl)-2H-benzotriazole, 2-(2′-hydroxyl-5′-t-butyl-3′-(methacryloyl oxyethyl) phenyl)-2H-benzotriazole, 2-(2′-hydroxyl-5′-(methacryloyl oxyethyl) phenyl)-5-chloro-2H-benzotriazole, and the like. Further, compounds having a large molecular weight, in which the ultraviolet absorbing skeleton is dimerized via methylene or the like, such as ADEKASUTABU LA31 (trade name, Adeka Corporation) and the like are also preferably used.

Examples of cyclic imino ester ultraviolet absorbing agents include 2, 2′-(1,4-phenylene) bis (4H-3,1-benzoxazinone-4-on, 2-methyl-3,1-benzoxazine-4-one, 2-buthyl-3, 1-benzoxazine-4-one, 2-phenyl-3,1-benzoxazine-4-one, 2-(1 or 2-naphthyl)-3,1-benzoxazine-4-one, 2-(4-biphenyl)-3,1- benzoxazine-4-one, 2-p-nitrophenyl-3,1-benzoxazine-4-one, 2-p-benzoylphenyl-3,1-benzoxazine-4-one, 2-p-methoxyphenyl-3,1-benzoxazine-4-one, 2-o-methoxyphenyl-3,1-benzoxazine-4-one, 2-cyclohexyl-3,1-benzoxazine-4-one, 2-p (or m)-phthalimidephenyl-3,1-benzoxazine-4-one, 2, 2′-(1,4-phenylene) bis (4H-3,1-benzoxazinone-4-one), 2,2′-bis (3,1-benzoxazine-4-one), 2, 2′-ethylenebis (3,1-benzoxazine-4-one), 2,2′-tetramethylenebis (3,1-benzoxazine-4-one), 2, 2′-decamethylenebis (3,1-benzoxazine-4-one), 2,2′-p-phenylenebis (3,1-benzoxazine-4-one), 2, 2′-m-phenylenebis (3,1-benzoxazine-4-one), 2, 2′-(4,4′-diphenylene) bis (3,1-benzoxazine-4-one), 2,2′-(2,6 - or 1,5-naphthalene) bis (3,1-benzoxazine-4-one), 2,2′-(2-methyl-p-phenylene) bis (3,1-benzoxazine-4-one), 2,2′-(2-nitro-p-phenylene) bis (3,1-benzoxazine-4-one), 2,2′-(2-chloro-p-phenylene) bis (3,1-benzoxazine-4-one), and 2,2′-(1,4-cyclohexylene) bis (3,1-benzoxazine-4-one).

Examples of cyclic imino ester ultraviolet absorbing agents further include 1,3,5-tri-(3,1-benzoxazine-4-one-2-yl) benzene, 1,3,5-tri-(3,1-benzoxazine-4-one-2-yl) naphthalene, and 2,4,6-tri (3,1-benzoxazine-4-one-2-yl) naphthalene.

Examples of cyclic imino ester ultraviolet absorbing agents still further include 2,8-dimethyl-4H,6H-benzo (1,2-d; 5,4-d′) bis-(1,3)-oxyazine-4,6-dione, 2,7-dimethyl-4H,9H-benzo (1,2-d; 5,4-d′) bis-(1,3)-oxyazine-4,9-dione, 2,8-diphenyl-4H,8H-benzo (1,2-d; 5,4-d′) bis-(1,3)-oxyazine-4,6-dione, 2,7-diphenyl-4H,9H-benzo (1,2-d; 5,4-d′) bis-(1,3)-oxyazine-4,6-dione, 6,6-bis (2-methyl-4H,3,1-benzoxazine-4-one), 6,6′-bis (2-ethyl-4H,3,1-benzoxazine-4-one), 6,6′-bis (2-phenyl-4H,3,1-benzoxazine-4-one), 6,6′-methylenebis (2-methyl-4H,3,1-benzoxazine-4-one), 6,6′-methylenebis (2-phenyl-4H,3,1-benzoxazine-4-one), 6,6′-ethylenebis (2-methyl-4H,3,1-benzoxazine-4-one), 6,6′-ethylenebis (2-phenyl-4H,3,1-benzoxazine-4-one), 6,6′-butylenebis (2-methyl-4H,3,1-benzoxazine-4-one), 6,6′-butylenebis (2-phenyl-4H,3,1-benzoxazine-4-one), 6,6′-oxybis (2-methyl-4H,3,1-benzoxazine-4-one), 6,6′-oxybis (2-methyl-4H,3,1-benzoxazine-4-one), 6,6′-oxybis (2-phenyl-4H,3,1-benzoxazine-4-one), 6,6′-sulfonylbis (2-methyl-4H,3,1-benzoxazine-4-one), 6,6′-sulfonylbis (2-phenyl-4H,3,1-benzoxazine-4-one), 6,6′-carbonylbis (2-methyl-4H,3,1 -benzoxazine-4-one), 6,6′-carbonylbis (2-phenyl-4H,3,1-benzoxazine-4-one), 7,7′-methylenebis (2-methyl-4H,3,1-benzoxazine-4-one), 7,7′-methylenebis (2-phenyl-4H,3,1-benzoxazine-4-one), 7,7′-bis (2-methyl-4H,3,1-benzoxazine-4-one), 7,7′-ethylenebis (2-methyl-4H,3,1-benzoxazine-4-one), 7,7′-oxybis (2-methyl-4H,3,1-benzoxazine-4-one), 7,7′-sulfonylbis (2-methyl-4H,3,1-benzoxazine-4-one), 7,7′-carbonylbis (2-methyl-4H,3,1-benzoxazine-4-one), and 6,7′-bis (2-methyl-4H,3,1-benzoxazine-4-one).

Examples of benzophenone series ultraviolet absorbing agents include 2,4-dihydroxybenzophenone, 2-hydroxy-4-methoxybenzophenone, 2-hydroxy-4-n-octyloxybenzophenone, 2,2′-dihydroxy-4-methoxybenzophenone, 2,2′-dihydroxy-4,4′-dimethoxybenzophenone, 2-hydroxyl-4-methoxy-5-sulfobenzophenone, and the like.

Examples of salicylic acid series ultraviolet absorbing agents include pheny salicylate, p-t-butylphenyl salicylate, p-n-octylphenyl salicylate, and the like.

Examples of cyanoacrylate series ultraviolet absorbing agents include 2-ethylhexyl-2-cyano-3-diphenylacrylate, and the like.

As for the light absorbing agent that absorbs ultraviolet light, an ink, called as invisible ink, which is invisible under visible light but becomes visible when irradiated with ultraviolet light can be used. Examples of such invisible inks include Invisible Ink # 214 and Invisible Ink #6330 manufactured by Union Corporation (which appear in blue when irradiated with ultraviolet light), and the like.

There is not any specific restriction on the composition of the substrate of the present invention. The present invention is suitably applicable to a photoelectric conversion device having a laminated structure of a lower electrode, a photoelectric conversion semiconductor layer that generates a current by absorbing light, and an upper electrode, and the like.

Example substrates used for photoelectric conversion devices include, glass substrates, such as soda-lime glass substrates, metal substrates, such as Al, Cu, Ti, stainless-steel substrates, anodized substrates constituted by an Al based metal base having an anodized film on at least one surface thereof, and resin substrates such as polyimide substrates.

In view of rapid manufacturing of photoelectric conversion devices by a continuous conveyance system (roll to roll process) and reduction in the thickness and weight thereof, it is preferable to use flexible substrates, such as anodized substrates, metal substrates with an insulation film formed thereon, or resin substrates.

When a resin substrate, such as a polyimide substrate, is used, it is necessary to form the photoelectric conversion layer at a temperature not higher than the heatproof temperature of the resin, limiting the process up to around 400° C. Some efforts, such as provision of an energy assist layer, are required since it is difficult to provide a high performance photoelectric conversion layer with such a temperature.

Preferably, the difference in thermal expansion coefficient between a substrate and each layer formed thereon is small in order to prevent warpage of the substrate due to thermal stress. From the viewpoint of difference in thermal expansion coefficient with the photoelectric conversion layer or lower electrode (rear electrode), cost, and characteristics required of solar cells, an anodized substrate constituted by an Al based metal base having an anodized film on at least one surface thereof is particularly preferable.

The “major component of the metal base” as used herein refers to a component that accounts for 98% by mass or more. The metal base may be a pure Al base that may include a trace element or an alloy base of Al with another metal element. As used herein, the “major component” of an electrode or a photoelectric conversion layer formed on a substrate, or any other layer provided as required refers to a component that accounts for 90% by mass or more.

In the substrate of the present invention, positioning of the substrate can be performed by irradiating a positioning marker provided on the substrate with detection light of a specific wavelength region, which is selectively absorbed or reflected by the positioning marker, and detecting reflection light from the marker.

That is, the substrate positioning method of the present invention is a method that uses a substrate having a positioning marker formed with a light absorbing agent that selectively absorbs light of a specific wavelength region or with a light reflecting agent that selectively reflects light of a specific wavelength region and performs positioning of the substrate by irradiating the positioning marker with detection light of the specific wavelength region and detecting reflection light from the marker.

In the present invention, a positioning marker is formed with a light absorbing agent or with a light reflecting agent and no hole is cut for providing the marker. Therefore, the marker can be formed on a substrate easily and a cleaning process for cleaning shavings that might be generated if a hole were provided is not required.

In the present invention, the marker can be detected by a light detection method using light of a specific wavelength region so that the positioning of the substrate may be performed accurately. In particular, the use of a marker that selectively absorbs or reflects near infrared light, infrared light, near ultraviolet light, or ultraviolet light may prevent influence of ambient light and allows high sensitive detection of a position of the substrate.

In the present invention, no hole is provided so that a marker can be formed on the rear surface of the substrate. Thus, it is not necessary to provide an edge, which is not eventually used, in the substrate. Consequently, according to the present invention, the entire surface of the substrate may be used effectively and a cutting process for cutting the edge is eliminated.

### [Photoelectric Conversion Device]

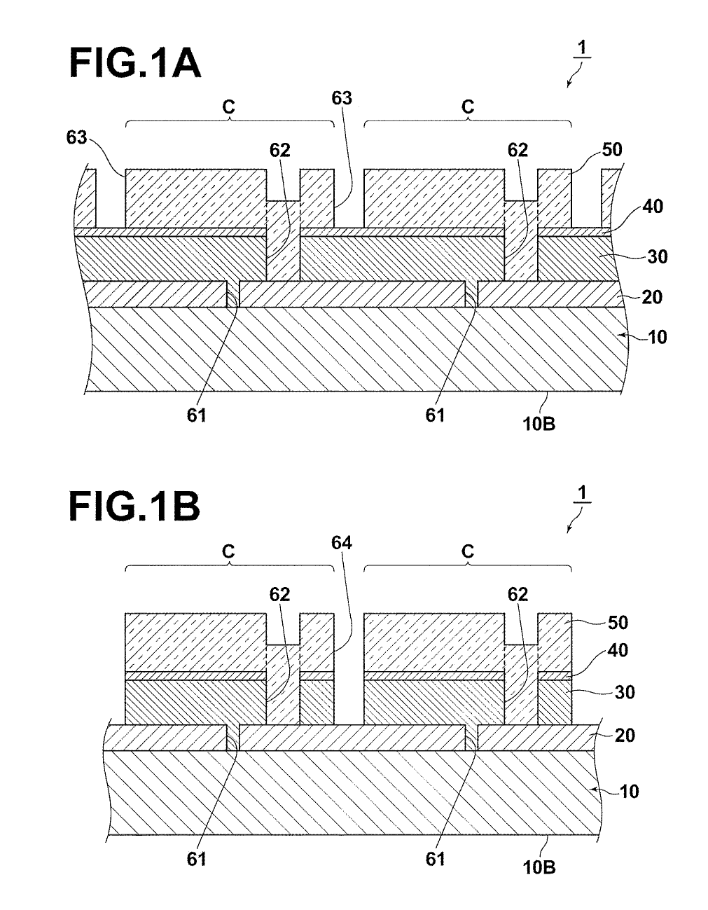

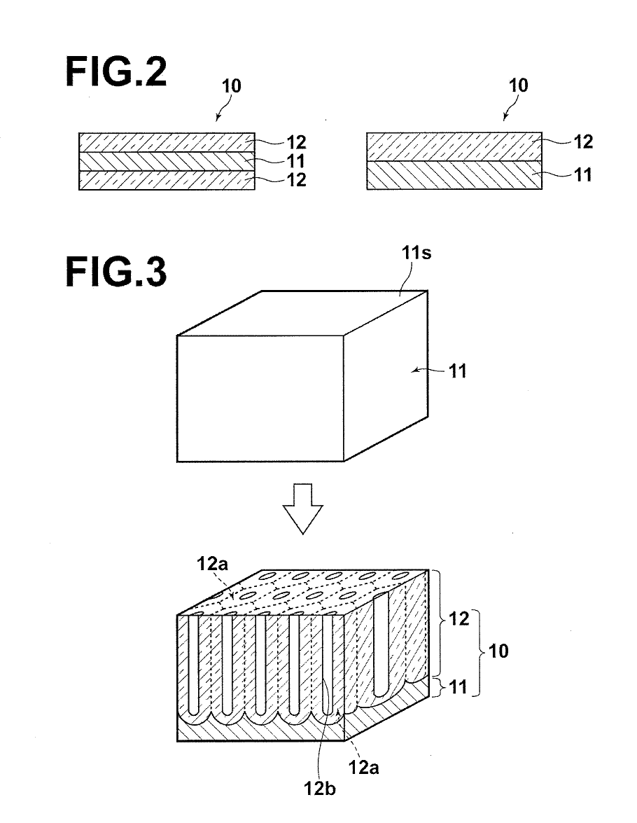

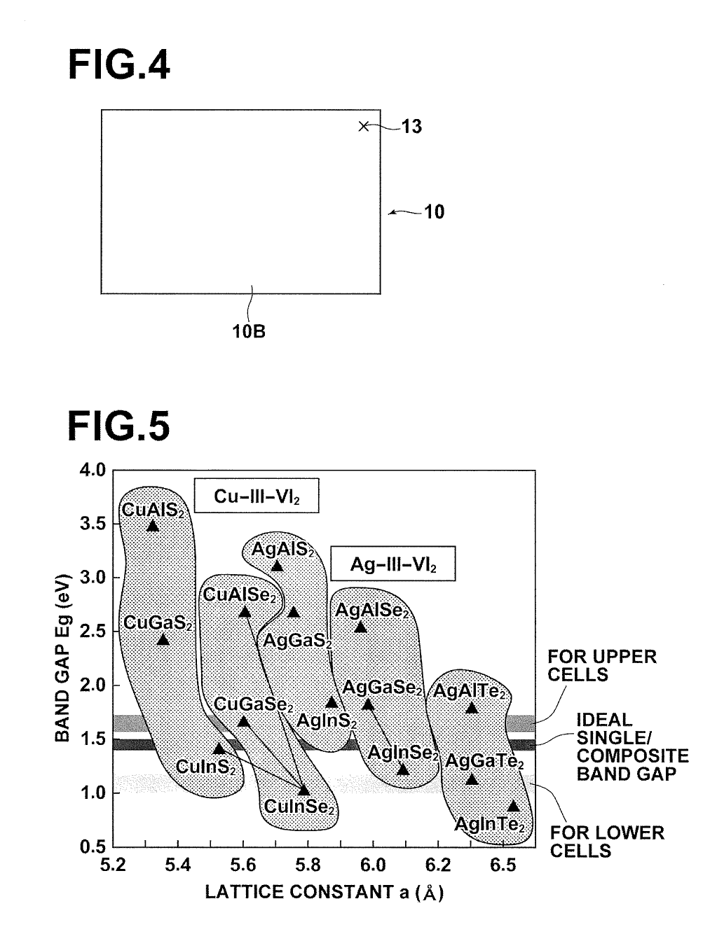

A structure of a photoelectric conversion device according to an embodiment of the present invention will be described with reference to the accompanying drawings. FIG. 1A is a schematic sectional view of the photoelectric conversion device in a lateral direction, and FIG. 1B is a schematic sectional view of the photoelectric conversion device in a longitudinal direction. FIG. 2 illustrates schematic sectional views of anodized substrates, FIG. 3 is a perspective view of an anodized substrate, illustrating a manufacturing method thereof, and FIG. 4 is a plan view of a substrate, illustrating the rear surface thereof. In the drawings, each component is not drawn to scale in order to facilitate visual recognition.

Photoelectric conversion device 1 is a device having substrate 10 on which lower electrode (rear electrode) 20, photoelectric conversion semiconductor layer 30, buffer layer 40, and upper electrode 50 are stacked in this order. Hereinafter, the photoelectric conversion semiconductor layer is abbreviated as “photoelectric conversion layer”.

Photoelectric conversion device 1 has first grooves 61 that run through only lower electrode 20, second grooves 62 that run through photoelectric conversion layer 30 and buffer layer 40, and third grooves 63 that run through only upper electrode layer 50 in a lateral sectional view and fourth grooves 64 that run through photoelectric conversion layer 30, buffer layer 40, and upper electrode layer 50 in a longitudinal sectional view.

The above configuration may provide a structure in which the device is divided into many cells C by first to fourth separation grooves 61 to 64. Further, upper electrode 50 is filled in second separation grooves 62, whereby a structure in which upper electrode 50 of a certain cell C is serially connected to lower electrode 20 of adjacent cell C may be obtained.

### (Anodized Substrate)

In the present embodiment, anodized substrate 10 is a substrate obtained by anodizing at least one surface of Al based metal base 11. Anodized substrate 10 maybe metal base 11 with anodized film 12 formed on each side, as illustrated on the left of FIG. 2 or metal base 11 with anodized film 12 formed on either one of the sides, as illustrated on the right of FIG. 2. Anodized film 12 is a film mainly consisting of Al₂O₃.

Preferably, substrate 10 is a substrate of metal base 11 with anodized film 12 formed on each side as illustrated on the left of FIG. 2 in order to prevent warpage of the substrate due to the difference in thermal expansion coefficient between Al and Al₂O₃, and detachment of the film due to the warpage during the device manufacturing process. The anodizing method for both sides may include, for example, a method in which anodization is performed on a side-by-side basis by applying an insulation material and a method in which both sides are anodized at the same time.

When anodized film 12 is formed on each side of anodized substrate 10, it is preferable that two anodized films are formed to have substantially the same film thickness or anodized film 12 on which a photoelectric conversion layer and some other layers are not provided is formed to have a slightly thicker film thickness than that of the anodized film 12 on the other side considering heat stress balance between each side.

Metal base 11 maybe Japanese Industrial Standards (JIS) 1000 pure Al or an alloy of Al with another metal element, such as Al—Mn alloy, Al—Mg alloy, Al—Mn—Mg alloy, Al—Zr alloy, Al—Si alloy, Al—Mg—si, or the like (“Aluminum Handbook”, Fourth Edition, published by Japan Light Metal Association, 1990). Metal base 11 may include traces of various metal elements, such as Fe, Si, Mn, Cu, Mg, Cr, Zn, Bi, Ni, Ti, and the like.

Anodization may be performed by immersing metal base 11, which is cleaned, smoothed by polishing, and the like as required, as an anode together with a cathode in an electrolyte, and applying a voltage between the anode and cathode. As for the cathode, carbon, aluminum, or the like is used. There is not any specific restriction on the electrolyte, and an acid electrolyte that includes one or more types of acids, such as sulfuric acid, phosphoric acid, chromic acid, oxalic acid, sulfamic acid, benzenesulfonic acid, amido-sulfonic acid, and the like, is preferably used. There is not any specific restriction on the anodizing conditions, which are dependent on the electrolyte used. Example anodizing conditions may include an electrolyte concentration of 1 to 80% by mass, a solution temperature of 5 to 70° C., a current density of 0.005 to 0.60 A/cm², a voltage of 1 to 200 V, and an electrolyzing time of 3 to 500 minutes.

As for the electrolyte, a sulfuric acid, a phosphoric acid, an oxalic acid, or a mixture thereof may preferably be used. When such an electrolyte is used, preferable anodizing conditions include an electrolyte concentration of 4 to 30% by mass, a solution temperature of 10 to 30° C., a current density of 0.05 to 0.30 A/cm², and a voltage of 30 to 150 V.

As shown in FIG. 3, when metal base 11 is anodized, an oxidization reaction proceeds from surface 11s in a direction substantially perpendicular to surface 11s, and Al₂O₃ based anodized film 12 is formed. Anodized film 12 generated by the anodization has a structure in which multiple fine columnar bodies, each having a substantially regular hexagonal shape in plan view, are tightly arranged. Each fine columnar body 12a has a fine pore 12b, substantially in the center, extending substantially linearly in a depth direction from surface 11s, and the bottom surface of each fine columnar body 12a has a rounded shape. Normally, a barrier layer without any fine pore 12b is formed (generally, with a thickness of 0.01 to 0.4 μm) at a bottom area of fine columnar bodies 12a. Anodized film 12 without any fine pore 12b may also be formed by appropriately arranging the anodizing conditions.

There is not any specific restriction on the diameter of fine pore 12b of anodized film 12. Preferably the diameter of fine pore 12b is 200 nm or less, and more preferably 100 nm or less from the viewpoint of surface smoothness and insulation properties. It is possible to reduce the diameter of fine pore 12b to about 10 nm.

There is not any specific restriction of the pore density of fine pores 12b of anodized film 12. Preferably, the pore density of fine pores 12b is 100 to 10000/μm², and more preferably 100 to 5000/μm², and particularly preferably 100 to 1000/μm² from the viewpoint of insulation properties.

There is not any specific restriction on the surface roughness Ra. From the viewpoint of uniformly forming the upper layer of photoelectric conversion layer 30, high surface smoothness is desirable. Preferably, the surface roughness Ra is 0.3 μm or less, and more preferably 0.1 μm or less.

There is not any specific restriction on the thicknesses of metal base 11 and anodized film 12. Preferably, the thickness of metal base 11 prior to anodization is, for example, 0.05 to 0.6 mm, and more preferably 0.1 to 0.3 mm in consideration of the mechanical strength of substrate 10, and reduction in the thickness and weight. When the insulation properties, mechanical strength, and reduction in the thickness and weight are taken into account, a preferable range of the thickness of anodized film 12 is 0.1 to 100 μm.

Fine pores 12b of anodized film 12 maybe sealed by any known sealing method as required. The sealed pores may increase the withstand voltage and insulating property. The sealed pores may increase the withstand voltage and insulating property. Further, if the pores are sealed using a material containing alkali metal ions, when photoelectric conversion layer 30 of CIGS or the like is annealed, the alkali metal, preferably Na, diffuses in photoelectric conversion layer 30, whereby the crystallization of photoelectric conversion layer 30, and hence photoelectric conversion efficiency, may sometimes be improved.

In the present embodiment, anodized substrate 10 is a substrate of the present invention having positioning marker 13 formed with a light absorbing agent that selectively absorbs light of a specific wavelength region or with a light reflecting agent that selectively reflects light of a specific wavelength region.

More specifically, as shown in FIG. 4, positioning marker 13 is formed on rear surface 10B of anodized substrate 10 using a light absorbing agent that selectively absorbs light of a specific wavelength region or a light reflecting agent that selectively reflects light of a specific wavelength region. In the present embodiment, positioning marker 13 is formed on rear surface 10B of substrate 10 where constituent layers of photoelectric conversion device 1 (electrodes, photoelectric conversion layer, and the like) are not formed, so that the marker can be formed at any position.

There is not any specific restriction on the shape and size of the positioning marker as long as it allows light detection. FIG. 4 shows positioning marker 13 having a “x” shape, as an example. The marker may be formed in a shape of line, dot, dotted line, or the like.

In the present embodiment, positioning of substrate 10 can be performed by irradiating positioning marker 13 with detection light of a specific wavelength region, which is selectively absorbed or reflected by the positioning marker, and detecting reflection light from positioning marker 13.

### (Photoelectric Conversion Layer)

Photoelectric conversion layer 30 is a layer that generates a current by absorbing light. There is not any specific restriction on the major component of the layer, and preferably the major component is at least one type of compound semiconductor having a chalcopyrite structure. Preferably, the major component of photoelectric conversion layer 30 is at least one type of compound semiconductor formed of a group Ib element, a group IIIb element, and a group VIb element.

As having a high light absorption rate and providing high photoelectric conversion efficiency, it is preferable that the major component of the photoelectric conversion layer is at least one type of compound semiconductor formed of at least one type of group Ib element selected from the group consisting of Cu and Ag, at least one type of group IIIb element selected from the group consisting of Al, Ga, and In, and at least one type of group VIb element selected from the group consisting of S, Se, and Te.

Examples of such compound semiconductors include CuAlS₂, CuGaS₂, CuInS₂, CuAlSe₂, CuGaSe₂, CuInSe₂ (CIS) , AgAlS₂, AgGaS₂, AgInS₂, AgAlSe₂, AgGaSe₂, AgInSe₂, AgAlTe₂, AgGaTe₂, AgInTe₂, Cu(In₁₋ₓGaₓ)Se₂ (CIGS) , Cu(In₁₋ₓAlₓ)Se₂, Cu(In₁₋ₓGaₓ) (S, Se)₂, Ag(In₁₋ₓGaₓ)Se₂, Ag(In₁₋ₓGaₓ) (S, Se)₂, and the like.

It is particularly preferable that photoelectric conversion layer 30 includes CuInSe₂ (CIS) , or a compound solidified with Ga, i.e, Cu(In, Ga)S₂ (CIGS) . CIS and CIGS are semiconductors having chalcopyrite structures and it is reported that they have high light absorption rates and high energy conversion efficiencies. Further, they are excellent in the durability with less deterioration in the conversion efficiency due to light exposure and the like.

Photoelectric conversion layer 30 includes an impurity for obtaining an intended semiconductor conductivity type. The impurity may be included in photoelectric conversion layer 30 by diffusing from an adjacent layer and/or by active doping.

Photoelectric conversion layer 30 may have a concentration distribution of constituent elements of group I-III-VI semiconductor and/or an impurity, and may have a plurality of layer regions of different semi-conductivities, such as n-type, p-type, i-type, and the like. For example, in a CIGS system, if Ga content of photoelectric conversion layer 30 is distributed in the thickness direction, band gap width/carrier mobility and the like can be controlled, whereby a higher photoelectric conversion efficiency value can be designed.

Photoelectric conversion layer 30 may include one or more types of semiconductors other than the group I-III-VI semiconductor.

Semiconductors other than the group I-III-VI semiconductor may include a semiconductor of group IVb element, such as Si (group IV semiconductor), a semiconductor of group IIIb element and group Vb element such as GaAs (group III-V semiconductor) , and a semiconductor of group IIb element and group VIb element, such as CdTe (group II-VI semiconductor).

Photoelectric conversion layer 30 may include any arbitrary component other than semiconductors and an impurity for causing the semiconductors to become an intended conductivity type within a limit that does not affect the properties.

As for the method of forming a CIGS layer, 1) multi-source simultaneous deposition, 2) selenization, 3) sputtering, 4) hybrid sputtering, 5) mechano-chemical process, and the like are known.

1) As for the multi-source simultaneous deposition, three-stage-growth process (J. R. Tuttle et al., “The Performance of Cu(In, Ga)Se₂-Based Solar Cells in Conventional and Concentrator Applications”, Mat. Res. Soc. Symp. Proc. Vol. 426, pp. 143-151, 1996, and the like) and simultaneous deposition of EC group (L. Stolt et al., “THIN FILM SOLAR CELL MODULES BASED ON CU(IN,GA)SE₂ PREPARED BY THE COEVAPORATION METHOD”, Proc. 13^{th}EUPVSEC, pp. 1451-1455, 1995, and the like) are known. The three-stage-growth process is a method in which In, Ga, and Se are deposited simultaneously in high vacuum at a substrate temperature of 300° C., then Cu and Se are deposited simultaneously by increasing the substrate temperature to 500 to 560° C., and In, Ga, and Se are further deposited simultaneously. The simultaneous deposition of EC group is a method in which Cu-excess CIGS is deposited in an early stage and In-excess CIGS is deposited in a latter stage.

Modifications of the methods described above for improving crystallization of a CIGS film include the following:

a) a method that uses ionized Ga (H. Miyazaki et al., “Growth of high-quality CuGaSe₂ thin films using ionized Ga precursor”, phys . Stat. sol. (a), Vol. 203, pp. 2603-2608, 2006, and the like);
b) a method that uses cracked Se (M. Kawamura et al., “Growth of Cu(In₁₋ₓGaₓ)Se₂ thin films using cracked selenium”, Proceedings of the 68th Autumn Meeting of the Japan Society of Applied Physics (held at Hokkaido Institute of Technology in 2007), Lecture No. 7p-L-6, and the like);
c) a method that uses radical Se (S. Ishizuka et al., “Preparation of Cu(In₁₋ₓGaₓ)Se₂ thin films using a Se-radical beam source and solar cell performance”, Proceedings of the 54th Spring Meeting of the Japan Society of Applied Physics (held at Aoyama Gakuin University in 2007), Lecture No. 29p-ZW-10, and the like); and
d) a method that uses photoexcited process (Y. Ishii et al., “High Quality CIGS Thin Films and Devices by Photo-Excited Deposition Process”, Proceedings of the 54th Spring Meeting of the Japan Society of Applied Physics (held at Aoyama Gakuin University in 2007), Lecture No. 29p-ZW-14, and the like).

2) Selenization, which is also called as a two-stage-growth process, is a method in which a metal precursor of a laminated film, such as Cu layer/In layer, (Cu—Ga) layer/In layer, or the like, is formed first by sputtering, deposition, or electrodeposition and then the metal precursor is heated to 450 to 550° C. in selenium vapor or in hydrogen selenide to forma selenium compound, such as Cu(In₁₋ₓGaₓ)Se₂ through thermal diffusion. This method is called as a vapor-phase selenization. Further, a solid-phase selenization in which solid-phase selenium is deposited on a metal precursor film and the metal precursor is selenized by solid-phase diffusion using the solid-phase selenium as the selenium source.

In selenization, the following two methods are known for preventing a rapid volume expansion that occurs at the time of selenization: a method in which selenium is mixed in the metal precursor film at a certain ratio in advance (T. Nakada et al., “CuInSe₂-based solar cells by Se-vapor selenization from Se-containing precursors”, Solar Energy Materials and Solar Cells, Vol. 35, pp. 209-214, 1994, and the like) ; and a method in which a multilayer precursor is formed by inserting selenium between metal thin films like, for example, Cu-layer/In-layer/Se-layer Cu-layer/In-layer/Se-layer (T. Nakada et al., “THIN FILMS OF CuInSe₂ PRODUCED BY THERMAL ANNEALING OF MULTILAYERS WITH ULTRA-THIN STACKED ELEMENTAL LAYERS”, Proceedings of the 10th European Photovoltaic Solar Energy Conference (EU PVSEC) , pp. 887-890, 1991, and the like).

Further, as a graded band gap CIGS film forming method, a method in which a Cu—Ga alloy film is deposited first, then an In film is deposited thereon, and, when selenizing the film, Ga concentration in the film thickness direction is graded by the natural thermal diffusion is known (K. Kushiya et al., Tech. Digest 9^{th} Photovoltaic Science and Engineering Conf. Miyazaki, 1996 (Intn. PVSEC-9, Tokyo 1996) p. 149, and the like).

3) As for the sputtering, the following methods are known:

a) a method the uses CuInSe₂ multicrystal as the target;
b) a two-source sputtering method that uses Cu₂Se and In₂Se₃ as the target and H₂Se/Ar mixed gas as the sputtering gas (J. H. Ermer et al., “CdS/CuInSe₂ JUNCTIONS FABRICATED BY DC MAGNETRON SPUTTERING OF Cu₂Se AND In₂Se₃”, Proceedings of the 18th IEEE Photovoltaic Specialists Conference, pp. 1655-1658, 1985); and
c) a three-source sputtering method in which Cu-target, In-target, and Se or CuSe target are sputtered in an Ar gas (T. Nakada et al., “Polycrystalline CuInSe₂ Thin Films for Solar Cells by Three-Source Magnetron Sputtering”, Japanese Journal of Applied Physics, Vol. 32, Part 2, No. 8B, pp. L1169-L1172, 1993, and the like).

4) As for the hybrid sputtering, a hybrid sputtering method in which Cu and In metals are DC sputtered and only Se is deposited in the sputtering method described above is known (T. Nakada et al., “Microstructural Characterization for Sputter-Deposited CuInSe₂ Films and Photovoltaic Devices”, Japanese Journal of Applied Physics, Vol. 34, Part 1, No. 9A, pp. 4715-4721, 1995, and the like).

5) The mechano-chemical process is a method in which materials according to the composition of a CIGS are put in a planet ball mill and the materials are mixed by mechanical energy to obtain CIGS powder, then the powder is applied to a substrate by screen printing and annealed to obtain a CIGS film (T. Wada et al., “Fabrication of Cu(In,Ga)Se₂ thin films by a combination of mechanochemical and screen-printing/sintering processes”, Physica status solidi (a), Vol. 203, No. 11, pp. 2593-2597, 2006, and the like).

6) Other CIGS film forming methods include screen printing, proximity sublimation, MOCVD, spraying, and the like. For example, a crystal having a desired composition may be obtained by forming a particle film that includes a group Ib element, a group IIIb element, and a group VIb element on a substrate and performing pyrolytic processing (which may be performed under the group VIb element atmosphere) on the particle film (Japanese Unexamined Patent Publication Nos. 9(1997)-074065 and 9(1997)-074213, and the like).

FIG. 5 illustrates the relationship between the lattice constant and band gap of major compound semiconductors. FIG. 8 shows that various band gaps may be obtained by changing the composition ratio. When a photon having a greater energy than the band gap is incident on a semiconductor, the amount of energy exceeding the band gap becomes heat loss. It has been known by a theoretical calculation that the conversion efficiency becomes maximal at about 1.4 to 1.5 eV in the combination between solar spectrum and band gap.

For example, Ga concentration in Cu(In, Ga)Seₑ (CIGS), Al concentration in Cu(In, Al)Se₂, or S concentration in Cu(In, Ga) (S, Se)2 may be increased to increase the band gap in order to increase the photoelectric conversion efficiency, whereby a high conversion efficiency band gap may be obtained. In the case of CIGS, the band gap may be adjusted in the range from 1.04 to 1.68 eV.

The band structure may be graded by varying the composition ratio in the film thickness direction. Two types of graded structures are known, one of which is a single graded band gap in which the band gap increases from the light entrance window side toward the electrode side on the opposite and the other of which is a double graded band gap in which the band gap decreases from the light entrance window side toward the PN junction and increases after passing the PN junction (T. Dullweber et al., “A new approach to high-efficiency solar cells by band gap grading in Cu(In, Ga)Se₂ chalcopyrite semiconductors”, Solar Energy Materials and Solar Cells, Vol. 67, pp. 145-150, 2001, and the like) . In either case, carriers induced by light are more likely to reach the electrode due to acceleration by an electric field generated inside thereof by the gradient of the band structure, whereby the probability of recombination in the recombination center is reduced and the photoelectric conversion efficiency is increased (U.S. Patent Application Publication No. 20060220059, and the like).

The use of a plurality of semiconductors having different band gaps with respect to each spectrum range may reduce heat loss due to discrepancy between photon energy and band gap and increase the power generation efficiency. The use of a plurality of such photoelectric conversion layers stacked on top of each other is referred to as tandem type. In the case of two-layer tandem, the power generation efficiency may be increased, for example, by the use of a combination of 1.1 eV and 1.7 eV.

### (Electrodes, Buffer Layer)

Each of lower electrode 20 and upper electrode 50 is made of a conductive material. Upper electrode 50 on the light input side needs to be transparent. There is not any specific restriction on the major component of lower electrode 20 and Mo, Cr, W, or a combination thereof is preferably used, in which Mo is particularly preferable. There is not any specific restriction on the thickness of lower electrode 20 and a value of 0.3 to 1.0 μm is preferably used.

There is not any specific restriction on the major component of upper electrode 50 and ZnO, ITO (indium tin oxide), SnO₂, or a combination thereof is preferably used. There is not any specific restriction on the thickness of upper electrode 50 and a value of 0.6 to 1.0 μm is preferably used. Lower electrode 20 and/or upper electrode 50 may have a single layer structure or a laminated structure, such as a two-layer structure. There is not any specific restriction on the method of forming lower electrode 20 and upper electrode 50, and vapor deposition methods, such as electron beam evaporation and sputtering may be used.

There is not any specific restriction on the major component of buffer layer 40 and CdS, ZnS, ZnO, ZnMgO, ZnS (O, OH) , or a combination thereof is preferably used. There is not any specific restriction on the thickness of buffer layer 40 and a value of 0.03 to 0.1 μm is preferably used. A preferable combination of the compositions is, for example, Mo lower electrode/CdS buffer layer/CIGS photoelectric conversion layer/ZnO upper electrode. There is not any specific restriction on the conductivity type of photoelectric conversion layer 30, buffer layer 40, and upper electrode 50. Generally, photoelectric conversion layer 30 is a p-layer, buffer layer 40 is an n-layer (n-Cds, or the like) , and upper electrode 50 is an n-layer (n-ZnO layer, or the like) or has a laminated structure of i-layer and n-layer (i-ZnO layer and n-ZnO, or the like) . It is believed that such conductivity types form a p-n junction or a p-i-n junction between photoelectric conversion layer 30 and upper electrode 50. Further, it is thought that provision of CdS buffer layer 40 on photoelectric conversion layer 30 results in an n-layer to be formed in a surface layer of photoelectric conversion layer 30 by Cd diffusion, whereby a p-n junction is formed inside of photoelectric conversion layer 30. It is also conceivable that an i-layer may be provided below the n-layer inside of photoelectric conversion layer 30 to form a p-i-n junction inside of photoelectric conversion layer 30.

Photoelectric conversion device 1 may further includes, as required, any layer other than those described above.

It is reported that, in a photoelectric conversion device using a soda lime glass substrate, an alkali metal element (Na element) in the substrate is diffused into the CIGS film, thereby improving energy conversion efficiency. In the present embodiment, it is also preferable to diffuse an alkali metal into the CIGS film. As for the alkali metal diffusion method, a method in which a layer including an alkali metal element is formed on a Mo lower electrode by deposition or sputtering as described, for example, in Japanese Unexamined Patent Publication No. 8 (1996) -222750, a method in which an alkali layer of Na₂S or the like is formed on a Mo lower electrode by soaking process as described, for example, in U.S. Pat. No. 7,018,858, a method in which a precursor of In, Cu, and Ga metal elements is formed on a Mo lower electrode and then, for example, an aqueous solution including sodium molybdate is deposited on the precursor, or the like may be cited.

It is also preferable to form lower electrode 20 in a laminated structure and a layer that includes one or more types of alkali metal compounds, such as Na2S, Na2Se, NaCl, NaF, and sodium molybdate salt, is formed between layers of the laminated structure. The layer may include a material that does not contain an alkali metal, such as alumina.

A close contact layer (buffer layer) may be provided, as required, between anodized substrate 10 and lower electrode 20, and/or between lower electrode 20 and photoelectric conversion layer 30 for enhancing the adhesion of the layers. Further, an alkali barrier layer for preventing diffusion of alkali ions may be provided, as required, between anodized substrate 10 and lower electrode 20. For details of the alkali barrier layer, refer to Japanese Unexamined Patent Publication No. 8 (1996) -222750.

Photoelectric conversion device 1 according to the present embodiment is structured in the manner as described above. Photoelectric conversion device 1 according to the present embodiment is a device that uses anodized substrate 10 so that it is lightweight and flexible, and can be manufactured by a continuous process (roll-to-roll process) with a reduced manufacturing cost.

In the present embodiment, marker 13 is formed on substrate 10 using a light absorbing agent or a light reflecting agent and no hole is cut for providing the marker. Therefore, positioning marker 13 can be formed on substrate 10 easily and a cleaning process for cleaning shavings that might be generated if a hole were provided is not required.

In the present invention, the marker can be detected by a light detection method using light of a specific wavelength region so that the positioning of the substrate may be performed accurately. In particular, the use of a marker that selectively absorbs or reflects near infrared light, infrared light, near ultraviolet light, or ultraviolet light may prevent influence of ambient light and allows high sensitive detection of a position of the substrate.

In the present invention, no hole is provided so that a marker can be formed on rear surface 10B of substrate 10. Thus, it is not necessary to provide an edge, which is not eventually used, to substrate 10. Consequently, according to the present invention, the entire surface of substrate 10 may be used effectively and a cutting process for cutting the edge is eliminated.

In the present embodiment, positioning of substrate 10 may be performed highly accurately when forming grooves 61 to 64. Consequently, grooves 61 to 64 may be formed with a high degree of accuracy and photoelectric conversion devices 1 may be manufactured with a high yield rate.

For example, after forming lower electrode 20, positioning of substrate 10 may be performed by irradiating positioning marker 13 with detection light of a specific wavelength region and detecting reflection light from positioning marker 13, and then a plurality of grooves 61 may be formed based on obtained position data of substrate 10, whereby the plurality of grooves 61 may be formed with a high degree of accuracy. The same is true for grooves 62 to 64.

In photoelectric conversion device 1, scribing appropriate for the quality and property of each film is performed. For example, in CIGS devices, first grooves 61 are normally formed by laser scribing and second to fourth grooves 62 to 64 are normally formed by mechanical scribing using a scribing blade.

It is preferable to provide marker 13 on rear surface 10B of substrate 10 without providing an edge which is eventually cut off, but a configuration may be adopted in which an edge to be eventually cut off is provided to substrate 10 and marker 13 is provided on the front or rear surface of the edge. In this case, the effective use of substrate 10 may not be achieved, but positioning marker 13 may be formed on substrate 10 easily, whereby an advantageous effect of accurate positioning of substrate 10 may be obtained. Photoelectric conversion device 1 may preferably be used as a solar cell. It can be turned into a solar cell by attaching, as required, a cover glass, a protection film, and the like.

### [Manufacturing Apparatus (Scribing Apparatus)]

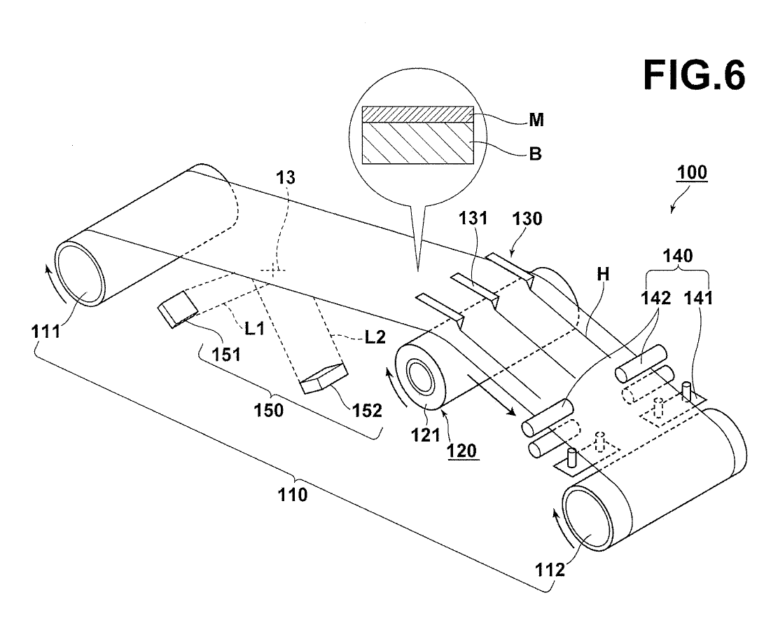

A structure of a manufacturing apparatus (scribing apparatus) according to an embodiment of the present invention will be described with reference to the accompanying drawing. FIG. 6 is a schematic perspective view of the apparatus.

The present embodiment is a manufacturing apparatus of photoelectric conversion device 1 according to the aforementioned embodiment and is a scribing apparatus for forming, after a laminated film of photoelectric conversion layer 30 and buffer layer 40 is formed, grooves 62 in the laminated film. Grooves 63 and 64 may also be formed by the apparatus.

Manufacturing apparatus (scribing apparatus) 100 of the present embodiment includes: a conveyor 110 for conveying a web of strip-like continuous flexible substrate B (anodized substrate 10) on which a target scribing film M (laminated film of photoelectric conversion layer 30 and buffer layer 40) is formed by applying a tensile strength to the flexible substrate B; a pressing unit 120 for pressing the flexible substrate B from a side on which the target subscribing film M is not formed; scriber 130 for scribing the target scribing film M formed on the surface of a portion of the flexible substrate B pressed by pressing unit 120; and substrate position detection unit 150.

Conveyor 110 roughly includes first turnable roller 111 (payout roller) for paying out the flexible substrate B and a second turnable roller 112 (rollup roller) for rolling up the flexible substrate B after subjected to the scribing. First roller 111 may be a conveyance roller for conveying the substrate from a previous process to the scribing process. Likewise, second roller 112 may be a conveyance roller for conveying the substrate from the scribing process to a next process.

Pressing unit 120 roughly includes a turnable pressing roller 121 for pressing flexible substrate B and a position adjustment mechanism (not shown) for adjusting the position of the roller 121 in up-down directions.

Scriber 130 roughly includes a plurality of scriber blades 131, disposed opposite to pressing roller 121 over the flexible substrate B, for performing mechanical scribing. The plurality of scriber blades 131 is arranged in the width direction of the flexible substrate B. The positions of each scriber blade 131 in the width direction of the substrate and up-down direction are adjustable. In FIG. 6, the reference symbols H represent grooves formed by the scribing.

Apparatus 100 of the present embodiment further includes meandering corrector 140, each having meandering detection sensor 141 and a plurality of meandering correction rollers 142.

Position detector 150 includes light irradiation unit 151 for irradiating positioning marker 13 shown in FIG. 4 with detection light L1 of a specific wavelength region and detection unit 152 for detecting reflection light L2 from positioning marker 13.

Light irradiation unit 151 includes a light source, such as a laser or a light emitting diode, and a light control/transmission optical system, such as a lens and an optical fiber provided as required. As for detection unit 152, a light receiving element that detects an optical property, such as intensity or wavelength spectrum, of reflection light L2 may be used. Examples of such elements/devices include optical densitometers, spectrophotometers, and various types of semiconductor optical sensors or phototubes with a filter that transmits (near) infrared light or (near) ultraviolet light attached thereto.

There is not any specific restriction on the shape and size of positioning marker 13 as long as it allows light detection. FIG. 6 shows positioning marker 13 having a “x” shape, as an example. The marker may be formed in a shape of line, dot, dotted line, or the like. For example, a line-like positioning marker 13 may be formed on either one or each end portion of the strip-like flexible substrate B along the width direction thereof.

Manufacturing apparatus (scribing apparatus) 100 of the present embodiment is structured in the manner as described above. According to the present embodiment, positioning of substrate B may be performed with a high degree of accuracy and grooves 62 to 64 may be formed with a high degree of accuracy. Position detector 150 is also applicable to the case in which grooves 61 are formed by laser scribing. In this case, a laser optical system for emitting laser light may be provided as the scriber.

The present invention is not limited to the embodiments described above, and design changes may be made as appropriate without departing from the sprit of the present invention.

The substrate and position detection method of the substrate according to the present invention are preferably applied to photoelectric conversion devices and the like. The photoelectric conversion device of the present invention may preferably be applied to solar cells, infrared sensors, and the like.

What is claimed is:

1. A substrate having a positioning marker formed with a light absorbing agent that selectively absorbs light of a specific wavelength region or with a light reflecting agent that selectively reflects light of a specific wavelength region.

2. The substrate of claim 1, wherein the light of a specific wavelength region is near infrared light, infrared light, near ultraviolet light, or ultraviolet light.

3. The substrate of claim 1, wherein the substrate is an anodized substrate constituted by an Al based metal base having an anodized film on at least one surface thereof.

4. The substrate of claim 1, wherein the substrate is a substrate for use with a photoelectric conversion device having a laminated structure that includes a lower electrode, a photoelectric conversion layer that generates a current by absorbing light, and an upper electrode.

5. A photoelectric conversion device, comprising a substrate on which a laminated structure is formed, the laminated structure including a lower electrode, a photoelectric conversion layer that generates a current by absorbing light, and an upper electrode, and being divided into a plurality of cells by a plurality of grooves,
wherein the substrate has a positioning marker formed with a light absorbing agent that selectively absorbs light of a specific wavelength region or with a light reflecting agent that selectively reflects light of a specific wavelength region.

6. The photoelectric conversion device of claim 5, wherein the light of a specific wavelength region is near infrared light, infrared light, near ultraviolet light, or ultraviolet light.

7. The photoelectric conversion device of claim 5, wherein the positioning marker is formed on a rear surface of the substrate.

8. A solar cell, comprising the photoelectric conversion device of claim 5.

9. A method of positioning a substrate in which a substrate having a positioning marker formed with a light absorbing agent that selectively absorbs light of a specific wavelength region or with a light reflecting agent that selectively reflects light of a specific wavelength region is used and positioning of the substrate is performed by irradiating the positioning marker with detection light of the specific wavelength region and detecting reflection light from the positioning marker.

10. A method of manufacturing a photoelectric conversion device having a substrate on which a laminated structure is formed, the laminated structure including a lower electrode, a photoelectric conversion layer that generates a current by absorbing light, and an upper electrode, and being divided into a plurality of cells by a plurality of groove,
wherein, the method uses, as the substrate, a substrate having a positioning marker formed with a light absorbing agent that selectively absorbs light of a specific wavelength region or with a light reflecting agent that selectively reflects light of a specific wavelength region and has a process of performing positioning of the substrate by irradiating the marker with detection light of the specific wavelength region and detecting reflection light from the positioning marker.

11. The method of claim 10, wherein the method further comprises, after the process of performing positioning of the substrate, a process of forming the plurality of grooves based on obtained position data of the substrate.

12. An apparatus for manufacturing the photoelectric conversion device of claim 5, comprising:
a light irradiation unit for irradiating the positioning marker with detection light of the specific wavelength range; and
a detection unit for detecting reflection light from the positioning marker.

13. The apparatus of claim 12, further comprising a scriber for forming the plurality of grooves.
